(19) United States
(12) Patent Application Publication
(10) Pub. No.: US 2026/0337760 A1
(43) Pub. Date: Oct. 29, 2026

(54) Embedding Method and Embedding System

(71) Applicant: Tokyo Electron Limited, Tokyo (JP)

(72) Inventors: Kenji SEKIGUCHI, Yamanashi (JP); Xiaolong LI, Yamanashi (JP)

(21) Appl. No.: 19/701,498

(22) Filed: Jun. 8, 2026

Related U.S. Application Data
(63) Continuation of application No. PCT/JP2024/043044, filed on Dec. 5, 2024.

(30) Foreign Application Priority Data
Dec. 18, 2023 (JP) 2023-212935

(51) Int. Cl. C23C 16/04; C23C 16/02; C23C 16/34; C23C 16/40; C23C 16/455; H10P 72/00; H10W 74/01

(52) U.S. Cl. CPC C23C 16/045; C23C 16/0227; C23C 16/345; C23C 16/402; C23C 16/45536; C23C 16/45544; H10P 72/0441; H10W 74/01

(57) ABSTRACT

An embedding method is provided. The embedding method comprises: preparing a structure in which a plurality of dies are arranged at intervals on a substrate; filling a gap between the plurality of dies with insulating fine particles; and forming an insulating film on a surface of the structure by ALD and embedding the insulating film in the gap, wherein an embedding layer in which the film is filled between the fine particles is formed in the gap.

### CROSS-REFERENCE TO RELATED APPLICATIONS

This application is a bypass continuation application of International Application No. PCT/JP2024/043044 having an international filing date of December 5, 2024 and designating the United States, the International Application being based upon and claiming the benefit of priority from Japanese Patent Application No. 2023-212935 filed on December 18, 2023, the entire contents of which are incorporated herein by reference.

### TECHNICAL FIELD

The present disclosure relates to an embedding method and an embedding system.

### BACKGROUND

Japanese Laid-open Patent Publication No. 2014-522115 discloses a technique in which, in an assembly with a plurality of die stacks formed on a base wafer, overmolding is performed on the base wafer using, e.g., film-assisted molding or compression molding of an electrically insulating material, in order to form a sealing structure between the die stacks.

### SUMMARY

The present disclosure provides an embedding method and an embedding system capable of embedding a low-stress film in a gap between a plurality of dies formed on a substrate at a low temperature and within a short period of time.

An embedding method according to one aspect of the present disclosure comprises: preparing a structure in which a plurality of dies are arranged at intervals on a substrate; filling a gap between the plurality of dies with insulating fine particles; and forming an insulating film on a surface of the structure by ALD and embedding the insulating film in the gap, wherein an embedding layer in which the film is filled between the fine particles is formed in the gap.

### BRIEF DESCRIPTION OF THE DRAWINGS

FIG. 1 is a flowchart illustrating an embedding method according to one embodiment.

FIG. 2A is a process cross-sectional view illustrating the embedding method according to one embodiment.

FIG. 2B is a process cross-sectional view illustrating the embedding method according to one embodiment.

FIG. 2C is a process cross-sectional view illustrating the embedding method according to one embodiment.

FIG. 3 is an SEM image showing a state in which SiO₂ (silica) fine particles are dispersed in chemical solution and embedded in a gap.

FIG. 4 illustrates five positions in a depth direction where an ALD film thickness was measured in the case of performing ALD film formation under three conditions of Cases 1 to 3 after filling a gap having a depth of 45 μm with SiO₂ fine particles.

FIG. 5 shows the relationship between a depth position and a ratio of a film thickness at that position to a film thickness at the top in the case of performing ALD film formation under three conditions of Cases 1 to 3 after filling a gap having a depth of 45 μm with SiO₂ fine particles.

FIG. 6 shows the relationship between a gap depth and a ratio of a film thickness to a film thickness at the top in the case of performing ALD film formation for fine particle sizes of 300 nm and 1500 nm.

FIG. 7 shows the relationship between a fine particle size and a depth loading, and between the fine particle size and a total time for ALD film formation in the case of executing a test in which an insulating film is formed by ALD after embedding insulating fine particles in a gap.

FIG. 8 is a diagram conceptually illustrating the relationship between a fine particle size and a depth loading, and between a fine particle size and a total ALD film formation time.

FIG. 9 is a block diagram showing an example of an embedding system for implementing the embedding method of one embodiment.

FIG. 10 is a cross-sectional view showing an example of a coating part of a fine particle filling apparatus used in the embedding system.

FIG. 11 is a longitudinal cross-sectional view showing an example of a film forming apparatus used in the embedding system.

FIG. 12 is a horizontal cross-sectional view showing an example of the film forming apparatus used in the embedding system.

### DETAILED DESCRIPTION

Hereinafter, the embodiments will be described in detail with reference to the accompanying drawings.

### Embedding method

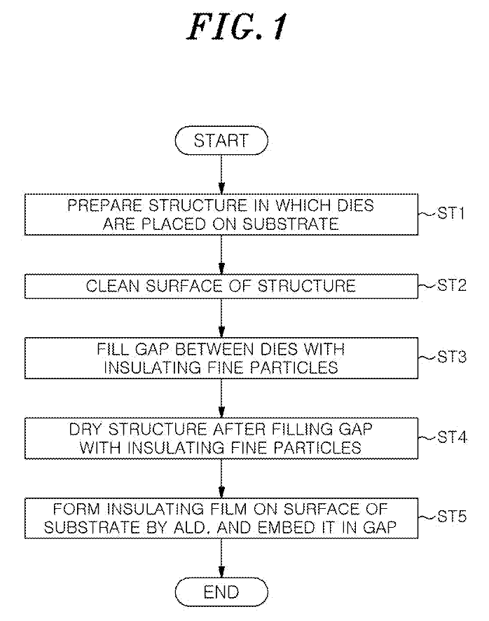

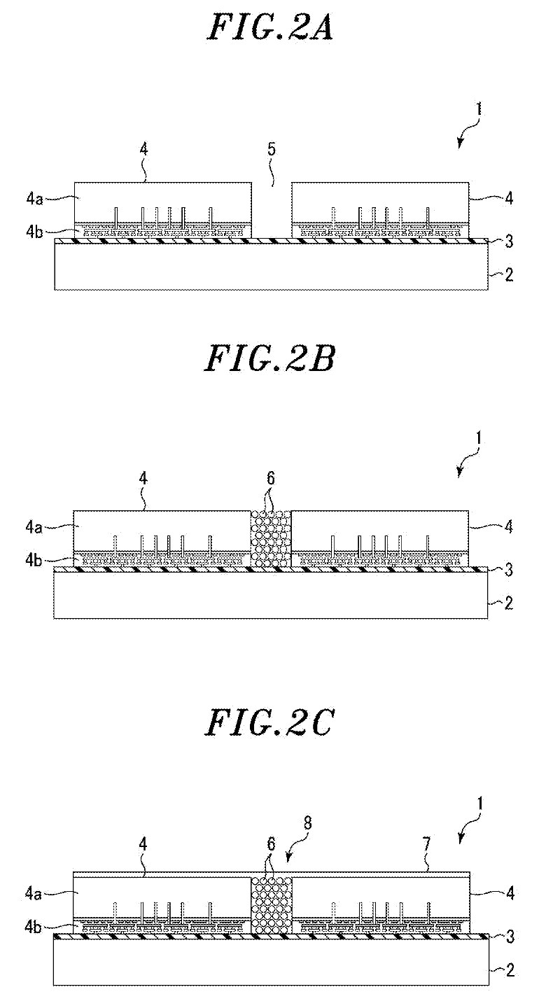

FIG. 1 is a flowchart illustrating an embedding method according to one embodiment. FIGS. 2A to 2C are process cross-sectional views illustrating the embedding method according to one embodiment. As shown in FIG. 1, the embedding method of the present embodiment includes steps ST1 to ST5. Step ST1 is a step of preparing a structure in which a plurality of dies are placed on a substrate. Step ST2 is a step of cleaning the surface of the structure. Step ST3 is a step of filling a gap between the dies with insulating fine particles. Step ST4 is a step of drying the structure after filling the insulating fine particles. Step ST5 is a step of forming an insulating film on the surface of the substrate by ALD and embedding the insulating film in the gap. Among these steps, steps ST1, ST3, and ST5 are the main steps. Step ST2 is executed as needed, and step ST4 is necessary when the insulating fine particles are filled into the gap while being dispersed in a solvent.

In step ST1, as shown in FIG. 2A, a structure 1 in which a plurality of dies 4 are arranged at intervals on a substrate 2 is prepared. The substrate 2 is, for example, a carrier wafer serving as a carrier substrate. The plurality of dies 4 may be mounted on the substrate 2 via an adhesive layer 3 made of an organic resin referred to as glue. Although the substrate 2 is illustrated as an example of a carrier substrate such as a carrier wafer, the substrate is not limited thereto and may have electrodes or wiring. The dies 4 may also be directly bonded to the substrate 2 by hybrid bonding or the like.

The die 4 is an IC chip formed by dicing a semiconductor wafer on which a semiconductor circuit has been formed, and includes a semiconductor base 4a and a circuit portion 4b formed on a surface portion thereof. The die 4 may be a single die or a stack of single dies. The width of the gap 5 between the dies 4 is, e.g., about 1 to 100 μm, and the depth of the gap 5 substantially corresponds to the height of the die 4, which may be within a range of about 20 μm to 100 μm.

In step ST2, the surface of the structure 1, i.e., the surfaces of the substrate 2 and the dies 4, is cleaned. The cleaning step is performed to remove organic components and to improve fillability of fine particles by improving hydrophilicity. The cleaning step may be executed using a chemical solution such as SC1 or SPM. The cleaning step may be single-wafer spin cleaning in which the structure 1 is rotated while supplying the chemical solution to the structure 1, or batch-type cleaning in which a plurality of structures 1 are immersed together in chemical solution. The cleaning step includes drying after cleaning.

In step ST3, as shown in FIG. 2B, the insulating fine particles 6 are filled into the gap 5 between the dies 4. The insulating fine particles 6 are not particularly limited as long as they are insulating, and may be made of inorganic material or organic material. For example, silica (SiO₂) may be preferably used as the insulating fine particles 6. The insulating fine particles 6 may also be silicon nitride (SiN). The insulating fine particles 6 may be spherical. Further, the size (particle diameter) of the insulating fine particles 6 may be within a range of 300 nm to 1500 nm, as will be described below.

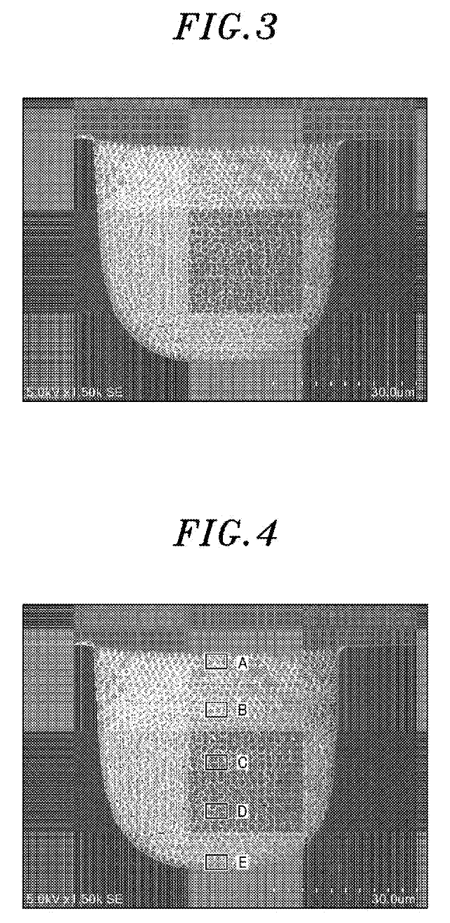

The state in which the insulating fine particles 6 are filled into the gap 5 is not particularly limited, and the insulating fine particles 6 may be in a state of being dispersed in a chemical solution having good dispersibility. The chemical solution for dispersing the insulating fine particles 6 is not particularly limited as long as it can disperse the insulating fine particles 6 effectively. The chemical solution may be, e.g., water, isopropyl alcohol (IPA), or ethylene glycol. These chemical solutions not only provide good dispersibility for the insulating fine particles 6 but can also be removed relatively easily. Water and IPA can be volatilized and removed at a temperature of about 60°C and ethylene glycol can be volatilized and removed at about 100°C by a short drying process of about 3 minutes. Among them, water is the most inexpensive. Further, ethylene glycol is advantageous in that its high surface tension can reduce particle residue on the substrate surface. FIG. 3 is an SEM image showing a state in which SiO_{₂} fine particles as the insulating fine particles 6 are dispersed in a chemical solution and embedded in the gap. As shown in FIG. 3, the SiO₂ fine particles are uniformly filled into the gap.

Methods for filling the insulating fine particles 6 into the gap 5 include dropping slurry, in which the insulating fine particles 6 are dispersed in a chemical solution, onto the structure 1, immersing the structure 1 in the slurry and lifting the structure 1 up, and dropping the slurry onto the structure 1 and rotating the substrate 2 to perform spin-coating. Spin-coating is preferable from the viewpoint of mass production because, for example, it allows the gap 5 to be filled with the insulating fine particles 6 using a smaller amount of slurry.

In step ST4, after embedding the insulating fine particles 6 in step ST3, drying is performed to remove the solvent in which the particles 6 are dispersed. The drying may be only baking, or may include baking followed by O₂ plasma treatment. O₂ plasma treatment is particularly effective when ethylene glycol is used as the solvent. Ethylene glycol tends to remain in the gap 5 even after baking, but can be completely removed by O₂ plasma.

In step ST5, as shown in FIG. 2C, in a state where the gap 5 is filled with the insulating fine particles 6, an insulating film 7 is formed on the surface of the structure 1 by ALD and embedded in the gap 5 between the dies 4. Accordingly, the insulating film 7 fills voids/spaces between the insulating fine particles 6 in the gap 5, thereby forming an embedding layer 8. Since the voids between the insulating fine particles 6 are filled by the insulating film 7, the embedding layer 8 exhibits high insulating properties with substantially no voids.

By using ALD to form the insulating film 7, a film can be formed at a temperature lower than 280°C, which is the heat-resistant temperature of glue used for the adhesive layer 3. When the dies 4 are directly bonded to the substrate 2, the heat resistance of the glue is not an issue. However, low-temperature film formation is similarly required in view of the heat resistance of the device. In this case as well, film formation by ALD is effective. A lower film formation temperature is preferable, and the lower the temperature, the better, and a temperature 100°C or less is preferable.

When the insulating film 7 is formed by ALD, a first reactant and a second reactant are alternately supplied to the structure 1 and the film formation is performed by the reaction thereof. Typically, a first step of supplying a source gas to the structure 1 and absorbing the source gas onto the structure 1, and a second step of supplying a reaction gas to the structure 1 to react the reaction gas with the source gas are repeated, thereby forming a film having a predetermined thickness. A purge step may be performed between the first step and the second step to exhaust residual gases.

The insulating film 7 is not particularly limited as long as it is insulating, and may be made of the same material as the insulating fine particles. An SiO₂ film or an SiN film is preferably used as the insulating film 7. When an SiO₂ film is formed by ALD, an Si-containing gas may be used as a source gas, and an oxygen-containing gas may be used as a reaction gas. Oxygen-containing plasma, such as O₂ plasma, is preferable as the oxygen-containing gas. When an SiN film is formed by ALD, an Si-containing gas may be used as a source gas, and a nitrogen-containing gas, such as N₂ plasma, may be used as a reaction gas. By utilizing ALD, the film formation can be easily performed at a temperature lower than 280°C that is the heat-resistant temperature of glue. When an SiO₂ film or an SiN film is formed by ALD, the film formation at a temperature below 100°C or lower, or even near room temperature, is possible by selecting types of source gas and reaction gas and other conditions.

The following are examples of combinations of a source gas and a reaction gas capable of forming an SiO₂ film as the insulating film 7.
Source gas | Reaction gas
(Me₂N)₃Si-SiH₃ | O₃ or O₂ plasma
(Me₂SiO)₄ | O₂ plasma
MeOSi(NCO)₃ | H₂O₂
Si(NCO)₄ | H₂O
Si(OEt)₄ | O₂ plasma
Si(OMe)₄ | H₂O
Si₂Cl₆ | O₃
SiCl₄ | H₂O
SiH(NMe₂)₃ | O₃ or H₂O, or O₂ plasma
SiH₂(NEt₂)₂ | O₃ or O₂ plasma
SiH₃N(iPr)₂ | O₃ or O₂ plasma
SiH₄ | N₂O plasma or CO₂ plasma
Further, when an SiN film is used as the insulating film 7, the following are examples of combinations of a source gas and a reaction gas.
Source gas | Reaction gas
N(Si₂H₅)₃ | N₂ plasma
N(SiH₃)₃ | N₂ plasma or NH₃ plasma
Si(SiH₃)₄ | N₂ plasma
SiH(NMe₂)₃ | N₂ plasma
SiH₂(NEt₂)₂ | N₂ plasma
SiH₄ | N₂ plasma
SiHMe₃ | NH₃ plasma
Si₂Cl₆ | NH₃

The insulating film 7 embedded in the gap 5 between the dies 4 by ALD in step ST5 is preferably a highly uniform film with low depth loading. As the uniformity of the film increases, the film stress can be reduced. The depth loading refers to a phenomenon in which the film formation amount at the portion (e.g., bottom of the gap) lower than the top of the gap is less than the film formation amount at the top of the gap.

For example, the diffusion of the reaction gas, such as O₂ plasma (O₂ radicals), during ALD affects the depth loading. In other words, by improving the diffusivity of the reaction gas, the film formation reaction proceeds even to the bottom of the gap 5, thereby reducing the depth loading.

The diffusivity of the reaction gas can be improved by increasing the supply time of the reaction gas. A test confirming this will be described below.

In this test, a gap having a depth of 45 μm was filled with SiO₂ fine particles having a particle size of 300 nm and, then, an SiO₂ film was formed by ALD to fill the gap. ALD was performed under three conditions (Cases 1 to 3) at a temperature 100°C or lower using diisopropylaminosilane (DIPAS (SiH₃N(iPr)₂)) as the source gas at a flow rate of 250 sccm, and O₂ plasma as the reaction gas. In Case 1, a pressure was set to 2 Torr, a source gas supply time was 4 sec, and an O₂ plasma supply time was 30 sec. Case 2 was the same as Case 1, except that the pressure was increased to 6 Torr. Case 3 was the same as Case 1, except that the O₂ plasma supply time was 120 sec, which is four times that of Case 1.

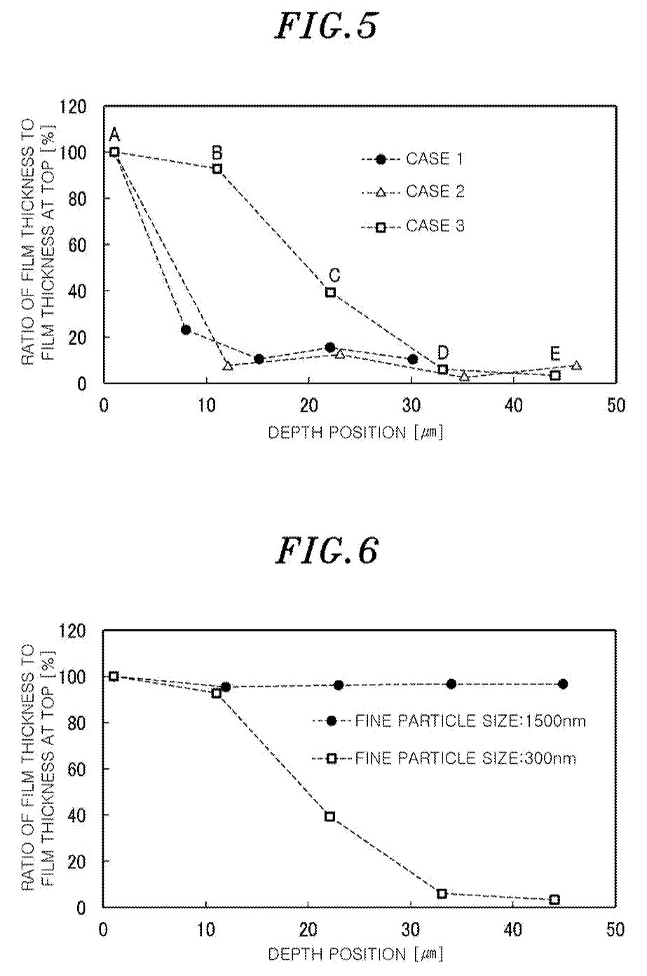

As shown in FIG. 4, the ALD film thickness was measured at five positions in the depth direction, i.e., position A: Top, position B: Top-Middle, position C: Middle, position D: Middle-Bottom, and position E: Bottom. FIG. 5 shows the relationship between the depth position of the gap and the ratio of the film thickness at each position to the film thickness at the top. As shown in FIG. 5, in Case 1, at the Top-Middle position (position B) where the depth is about 10 μm, the ratio of the film thickness to the film thickness at the top already decreased to about 20%, indicating the depth loading is large. In Case 2, there is almost no improvement in depth loading. In contrast, in Case 3, the ratio of the film thickness to the film thickness at the Top is 90% or higher at the Top-Middle position (position B), which indicates improvement in depth loading.

The lack of improvement of depth loading in Case 2 is considered to be because an increase in pressure results in a high concentration gradient of the source gas and a faster diffusion rate, but the diffusion of O₂ plasma (O₂ radicals) does not progress. On the other hand, during the supply of O₂ plasma that is the reaction gas, an automatic pressure control valve (APC valve) is generally opened to discharge by-products, thereby lowering the pressure and resulting in a low concentration gradient. Therefore, it is considered that by increasing the supply time of O₂ plasma (O₂ radicals) as in Case 3, the diffusion of O₂ plasma (O₂ radicals) progresses, resulting in improvement in depth loading.

However, as shown in FIG. 5, there is a limit to the improvement in depth loading that can be achieved by adjusting the reaction gas supply time.

As a technique for facilitating the diffusion of the reaction gas during ALD film formation, it is effective to increase the size (particle diameter) of the insulating fine particles 6. In other words, by increasing the size of the insulating fine particles 6, the gap between the particles becomes larger, which improves the diffusivity of the reaction gas and makes the film formation reaction proceed even to the bottom portion of the gap.

FIG. 6 shows the relationship between the depth of the gap and the ratio of film thickness to the film thickness at the top when ALD film formation is performed under the conditions of Case 3, for cases where the insulating fine particle size is 300 nm and 1500 nm. As shown in FIG. 6, a film is hardly formed at the bottom when the fine particle size is 300 nm, whereas a film thickness equivalent to that at the top is obtained at the bottom by setting the fine particle size to 1500 nm, showing that the depth loading is nearly zero. In other words, when the size of the insulating fine particles 6 is small, the gap between particles is small and, thus, it is difficult for the reaction gas to diffuse. Accordingly, the top is quickly closed and the depth loading increases. When the size of the insulating fine particles 6 increases, the diffusivity of the reaction gas is improved and, thus, the depth loading decreases.

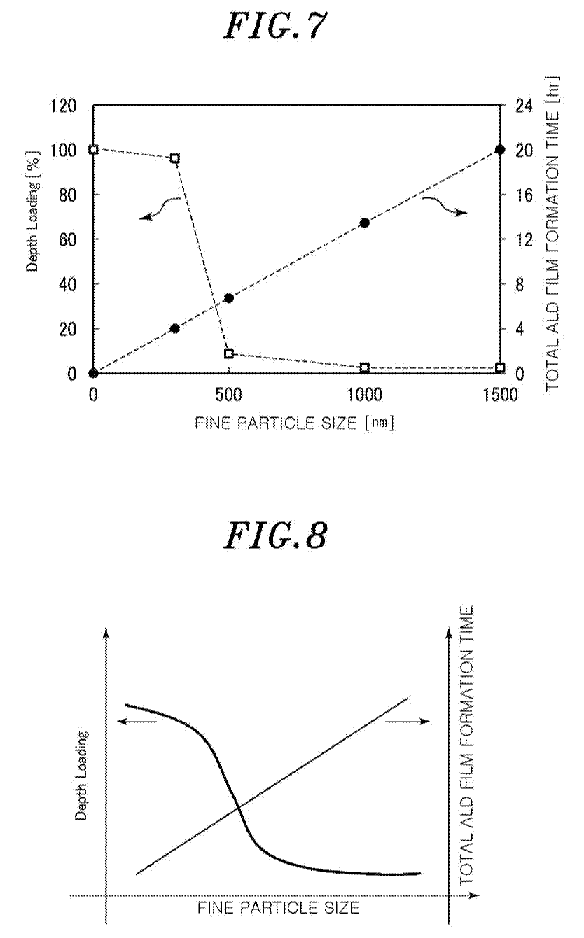

In the case of performing ALD film formation under the conditions of Case 3, the relationship between the size of the insulating fine particles 6 and the depth loading (the ratio of the film formation amount at the bottom to the film formation amount at the top) is as shown in FIG. 7. In other words, when the size of the insulating fine particles 6 exceeds 300 nm, the depth loading decreases abruptly, and tends to saturate when the size exceeds 500 nm. On the other hand, the total time for ALD film formation increases as the size of the insulating fine particles 6 increases, as shown in FIG. 7. This is because gaps between the fine particles increase.

In other words, the relationship between the particle size and the depth loading, and the relationship between the particle size and the total time for ALD film formation are conceptually shown in FIG. 8. From FIG. 8, it is clear that an optimal particle size that achieves both low depth loading and short total ALD film formation time exists.

Conventionally, as in Japanese Laid-open Patent Publication No. 2014-522115, a technique for filling the gap between dies using molding has been employed. However, this requires baking at a temperature higher than or equal to the heat resistance temperature of glue, which may adversely affect the device. Further, high stress causes warpage of the substrate. Although filling the gap using PE-CVD has also been performed, using only thin-film formation techniques such as CVD requires a long period of time to fill a gap having a depth of 20 μm to 100 μm. Further, stress of the embedded film is also high, which again leads to warpage of the substrate.

In contrast, according to the present embodiment, the insulating film 7 is formed by ALD after filling the gap 5 between the dies 4 with the insulating fine particles 6, so that the film formation can be performed at a low temperature and the gap can be embedded within a short period of time. In other words, in the case of filling the gap 5 with the insulating fine particles 6, there is no need for high-temperature baking as in molding. Even when the insulating fine particles 6 are filled while being dispersed in chemical solution, it is sufficient to perform heating to about 100°C to remove the chemical solution. The formation of the insulating film 7, which is subsequent thereto, is also performed by ALD, and thus can be performed at a low temperature. Further, by performing the film formation by ALD after filling the gap 5 with the insulating fine particles 6, it is possible to significantly shorten the embedding time compared to the case of performing ALD from the beginning. Moreover, by adopting the method of filling the gap with the insulating fine particles 6 and then forming the insulating film 7 by ALD, both the ALD time and the film uniformity can be achieved by adjusting a particle size, and the film stress can also be minimized.

### Embedding system

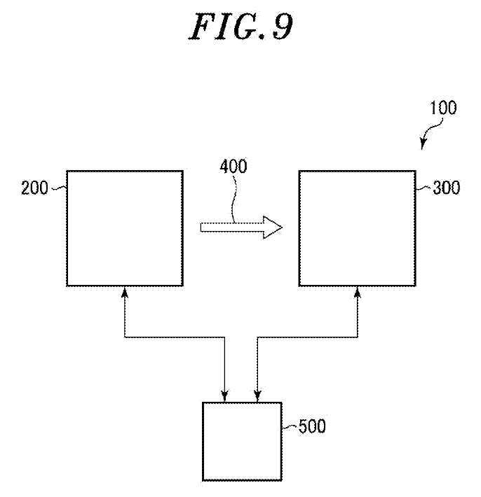

Next, an example of an embedding system for performing the above-described embedding method of one embodiment will be described. FIG. 9 is a block diagram illustrating an example of an embedding system.

As shown in FIG. 9, an embedding system 100 includes a fine particle filling apparatus 200, a film forming apparatus 300, a transfer device 400, and a control part 500.

### Fine particle filling apparatus

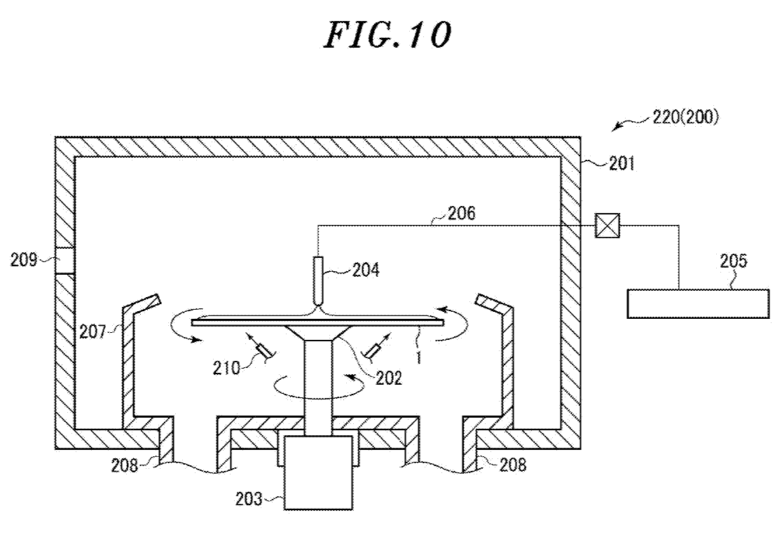

FIG. 10 is a cross-sectional view illustrating an example of a coating part 220 of the fine particle filling apparatus 200. In the fine particle filling apparatus 200, slurry in which insulating fine particles are dispersed in chemical solution is applied to a surface of a structure 1 in which a plurality of dies are mounted on a substrate by the coating part 220, and the slurry is dried by a drying part (not shown) to fill gaps between a plurality of dies with the insulating fine particles.

As shown in FIG. 10, the coating part 220 of the fine particle filling apparatus 200 includes a chamber 201, a spin chuck 202 that rotatably holds the structure 1 in the chamber 201, a motor 203 that rotates the spin chuck 202, and a nozzle 204 that injects the slurry onto the structure 1 held on the spin chuck 202. The slurry is supplied to the nozzle 204 from a slurry supply mechanism 205 through a line 206. A cup 207 for covering the structure 1 held on the spin chuck 202 is provided in the chamber 201, and a drain line 208 is provided at the bottom portion of the cup 207. A loading/unloading port 209 for loading/unloading the structure 1 is provided in the sidewall of the chamber 201. A back rinse nozzle 210 is provided on the back surface side of the structure 1 held on the spin chuck 202.

In the fine particle filling apparatus 200 configured as described above, in the coating part 220, the slurry in which insulating fine particles such as silica are dispersed in chemical solution is supplied from the slurry supply mechanism 205 to the nozzle 204 through the line 206. The slurry is injected from the nozzle 204 onto the surface of the structure 1 and, then, the structure 1 is rotated via the spin chuck 202 by the motor 203, thereby applying the slurry onto the surface of the structure 1. Accordingly, the insulating fine particles dispersed in the chemical solution are filled into gaps between a plurality of dies. Then, in the drying part, the chemical solution is volatilized and removed, leaving only the insulating fine particles filled in the gaps.

### Film forming apparatus

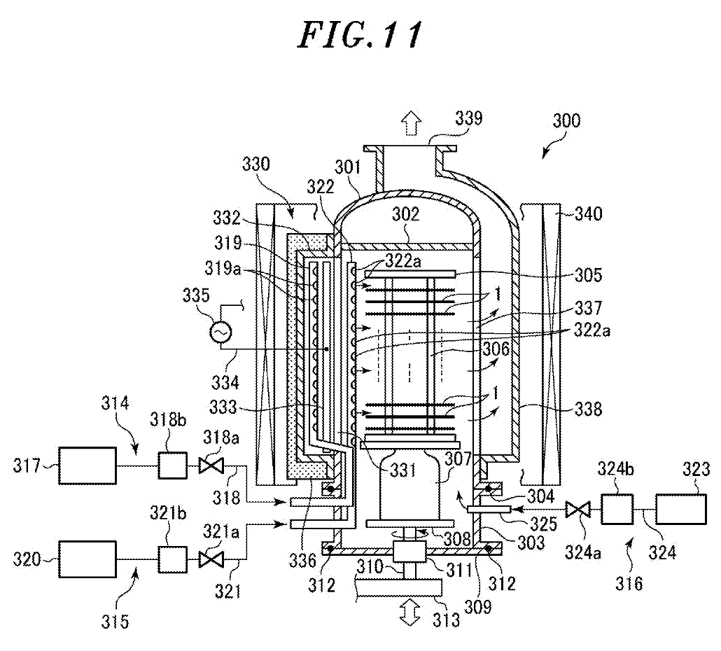

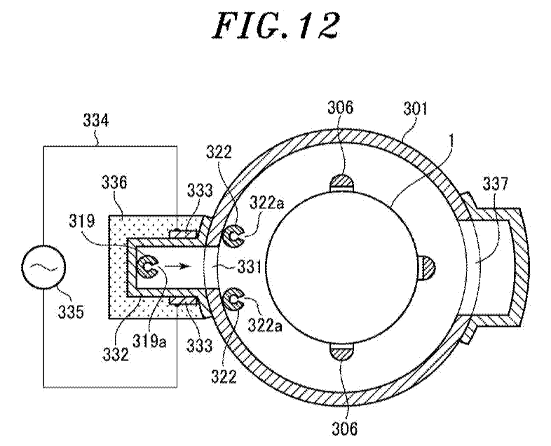

FIG. 11 is a longitudinal cross-sectional view illustrating an example of the film forming apparatus 300. FIG. 12 is a horizontal cross-sectional view illustrating an example of the film forming apparatus 300. The film forming apparatus 300 forms an insulating film on the surface of the structure 1, after filling the gap with insulating fine particles, using ALD to embed the film in the gap. The apparatus is configured as a vertical batch-type film forming apparatus. In this example, a Si-containing gas is supplied as a source gas, and O₂ plasma is supplied as a reaction gas to form an SiO₂ film as an insulating film.

The film forming apparatus 300 includes a cylindrical processing chamber 301 having an open lower end and an upper end sealed by a ceiling plate 302. The processing chamber 301 and the ceiling plate 302 are made of quartz, for example. A metal manifold 303 formed in a cylindrical shape, for example, is connected to the lower open end of the processing chamber 301 via a sealing member such as an O-ring 304.

The manifold 303 supports the lower end of the processing chamber 301. A quartz boat 305, capable of holding a plurality of structures 1 (e.g., 50 to 100 structures) after fine particle filling in multiple stages, can be inserted into the processing chamber 301 from a position below the manifold 303. The boat 305 includes three support rods 306 (see FIG. 12), and the plurality of structures 1 can be supported by grooves formed at the rods.

The boat 305 is placed on a table 308 via a heat insulation cylinder 307 made of quartz, for example. The table 308 is supported on a rotary shaft 310 penetrating through a metal lid 309 that opens and closes the lower end opening of the manifold 303.

A magnetic fluid seal 311 is provided at the portion where the rotary shaft 310 penetrates to airtightly seal the rotary shaft 310 while allowing rotation. A sealing member 312 is interposed between the peripheral portion of the lid 309 and the lower end of the manifold 303, thereby maintaining the airtightness of the processing chamber 301.

The rotary shaft 310 is attached to the tip end of an arm 313 supported by a lifting mechanism (not shown), so that the boat 305 and lid 309 are integrally raised or lowered for insertion into and removal from the processing chamber 301. Alternatively, the table 308 may be fixed to the lid 309 side, and the film formation may be performed without rotating the boat 305.

The film forming apparatus 300 further includes an O₂ gas supply mechanism 314 for supplying O₂ gas into the processing chamber 301, a Si-containing gas supply mechanism 315 for supplying a Si-containing gas as a source gas, and a purge gas supply mechanism 316 for supplying an inert gas, such as N₂ gas, as a purge gas into the processing chamber 301.

The O₂ gas supply mechanism 314 includes an O₂ gas source 317, an O₂ gas line 318 for guiding the gas from the O₂ gas source 317, and an O₂ gas dispersion nozzle 319 connected to the line 318 and extending vertically upward while penetrating inward through the sidewall of the manifold 303. A plurality of gas injection holes 319a spaced apart from each other at predetermined intervals are formed at the vertical portion of the O₂ gas dispersion nozzle 319, so that O₂ gas can be substantially uniformly injected from the gas injection holes 319a into the processing chamber 301 in a horizontal direction.

The Si-containing gas supply mechanism 315 includes a Si-containing gas source 320, a Si-containing gas line 321 for guiding the gas from the Si-containing gas source 320, and a Si-containing gas dispersion nozzle 322 made of a quartz tube, connected to the Si-containing gas line 321 and extending vertically upward while penetrating through the sidewall of the manifold 303. Two Si-containing gas dispersion nozzles 322 are provided (see FIG. 12). A plurality of gas injection holes 322a are formed at each of the Si-containing gas dispersion nozzles 322 along the lengthwise direction of the nozzle to substantially uniformly inject a Si-containing gas into the processing chamber 301 in a horizontal direction. There may be only one Si-containing gas dispersion nozzle 322.

The purge gas supply mechanism 316 includes a purge gas source 323, a purge gas line 324 for guiding the gas from the purge gas source 323, and a purge gas nozzle 325 connected to the purge gas line 324 and penetrating through the sidewall of the manifold 303.

The O₂ gas line 318, the Si-containing gas line 321, and the purge gas line 324 are provided with opening/closing valves 318a, 321a, and 324a and flow rate controllers 318b, 321b, and 324b, such as mass flow controllers, to supply an O₂ gas, a Si-containing gas, and a purge gas, while respectively controlling the flow rates thereof.

A plasma generation mechanism 330 for generating O₂ plasma by exciting O₂ gas is provided at a part of the sidewall of the processing chamber 301. The plasma generation mechanism 330 has a plasma partition wall 332 made of, e.g., quartz, which is hermetically attached to the outer wall of the processing chamber 301 to cover an opening 331 from the outside, the opening 331 being formed by cutting out the sidewall of the processing chamber 301 along the vertical direction. The plasma partition wall 332 protrudes from the processing chamber 301, and its internal space communicates with the processing space in the processing chamber 301. Further, the plasma generation mechanism 330 includes a pair of elongated plasma electrodes 333 arranged on the outer surfaces of both sidewalls of the plasma partition wall 332 to face each other along the vertical direction, and a high-frequency power supply 335 connected to the plasma electrodes 333 through a power supply line 334. The opening 331, the plasma partition wall 332, and the plasma electrodes 333 are formed to cover all the structures 1 held in the boat 305 in the height direction. The O₂ gas dispersion nozzle 319 extends upward along the innermost portion of the plasma partition wall 332. O₂ plasma is generated by applying a high-frequency voltage of, e.g., 13.56 MHz, from the high-frequency power supply 335 to the plasma electrodes 333 while injecting O₂ gas from the gas injection holes 319a of the O₂ gas dispersion nozzle 319. O₂ plasma is diffused toward the processing chamber 301 and supplied to each structure 1. An insulating protective cover 336 is attached to the outside of the plasma partition wall 332 so as to cover it.

An exhaust port 337 for vacuum evacuation, which is formed by cutting the processing chamber 301 into a vertically elongated shape, is provided on the opposite side of the opening 331 of the processing chamber 301. An exhaust port cover member 338 is attached to the processing chamber 301 to cover the exhaust port 337. The exhaust port cover member 338 extends upward along the sidewall of the processing chamber 301, and defines an exhaust channel and a gas outlet 339 located above the processing chamber 301. The processing chamber 301 is evacuated from the gas outlet 339 by a vacuum exhaust system (not shown). A cylindrical heating device 340 is provided to heat the inside of the processing chamber 301 while surrounding the outer circumference of the processing chamber 301.

In the film forming apparatus configured as above, first, at room temperature, the boat 305 holding 50 to 100 structures 1, for example, is raised from below and loaded into the processing chamber 301 controlled to a predetermined temperature. Then, the processing chamber 301 is sealed by closing the lower end opening of the manifold 303 with the lid 309.

Then, the processing chamber 301 is evacuated and maintained at a predetermined process pressure. The power supply to the heating device 340 is controlled to maintain the temperature of the processing chamber 301 at the process temperature, and the film formation is started while rotating the boat 305. In this case, the film formation is performed by ALD in which a first step of supplying a Si-containing gas as a source gas into the processing chamber 301 and adsorbing it onto the structures 1, and a second step of suppling O₂ plasma (O₂ radicals) produced by exciting O₂ gas as a reaction gas into the processing chamber 301 and allowing it to react with the Si-containing gas as a source gas. Accordingly, an SiO₂ film of a predetermined thickness is formed and embedded in the gap of the structures 1. After the first and second steps, a purge step in which a purge gas is supplied to remove residual gases from the processing chamber 301 is performed.

By forming an SiO₂ film using ALD with a Si-containing gas as a source gas and O₂ plasma (O₂ radicals) as a reaction gas, the SiO₂ film can be embedded in the gap at a temperature lower than the heat-resistant temperature (about 280°C) of glue used as an adhesive layer. In particular, by using aminosilane gas such as diisopropylaminosilane (DIPAS (SiH₃N(iPr)₂)) as a Si-containing gas, the film formation can be performed at a temperature of 100°C or lower.

### Transfer device

The transfer device 400 transfers the structures 1 from the fine particle filling apparatus 200 to the film forming apparatus 300. The plurality of structures 1 are transferred while being accommodated in a storage container. The transfer device 400 may transfer the structures 1 while maintaining the storage container under vacuum or an inert atmosphere.

### Control part

The control part 500 controls the fine particle filling apparatus 200, the film forming apparatus 300, and the transfer device 400 that constitute the embedding system 100. The control part 500 includes a main controller having a CPU, an input device, an output device, a display device, and a storage device. The main controller of the control part 500 causes the embedding system 100 to perform a desired operation based on a process recipe stored in a storage medium built into the storage device or set in the storage device.

In the embedding system 100, the embedding method of the present embodiment can be realized by operating the fine particle filling apparatus 200 and the film forming apparatus 300 as described above under control of the control part 500.

The embedding system 100 may further include a cleaning apparatus for cleaning the structures 1 before filling the gap with insulating fine particles, and a transfer device for transferring the structures 1 from the cleaning apparatus to the fine particle filling apparatus 200.

### Other applications

While the embodiments of the present disclosure have been described, the embodiments of the present disclosure are illustrative in all respects and are not restrictive. The above-described embodiments may be omitted, replaced, or changed in various forms without departing from the scope of the appended claims and the gist thereof.

For example, although an apparatus that spin-coats a structure with insulating fine particles dispersed in chemical solution has been described as an example of the fine particle filling apparatus of the above embodiment, the present disclosure is not limited thereto. The insulating fine particles may be filled by immersing the structure in chemical solution in which the insulating fine particles are dispersed and then lifting it up. In this case, a batch-type fine particle filling apparatus capable of filling fine particles into a plurality of structures may be used.

Although a vertical batch-type film forming apparatus has been described as an example of the film forming apparatus, the present disclosure is not limited thereto. A single-wafer type film forming apparatus that places a structure on a stage and performs ALD film formation may also be used.

1. An embedding method comprising:
preparing a structure in which a plurality of dies are arranged at intervals on a substrate;
filling a gap between the plurality of dies with insulating fine particles; and
forming an insulating film on a surface of the structure by ALD and embedding the insulating film in the gap,
wherein an embedding layer in which the film is filled between the fine particles is formed in the gap.

2. The method of claim 1, wherein the substrate is a carrier substrate, and the dies are adhered to the substrate via an adhesive layer.

3. The method of claim 1, further comprising:
cleaning a surface of the structure before said filling the gap with the fine particles.

4. The method of claim 1, wherein the fine particles and the film are made of the same material.

5. The method of claim 1, wherein said embedding the film is performed at a temperature 100°C or lower.

6. The method of claim 1, wherein filling the gap with the fine particles is performed while the fine particles are dispersed in a chemical solution.

7. The method of claim 6, wherein the solution is water, isopropyl alcohol, or ethylene glycol.

8. The method of claim 6, further comprising:
drying the structure after said filling the gap with the fine particles.

9. The method of claim 1, wherein the fine particles have a size of 300 nm to 1500 nm.

10. The method of claim 1, wherein the fine particles comprise SiO₂ or SiN.

11. The method of claim 1, wherein said embedding the film comprises embedding an SiO₂ film by alternately supplying a Si-containing gas and an oxygen-containing gas.

12. The method of claim 11, wherein the oxygen-containing gas is O₂ plasma.

13. The method of claim 1, wherein said embedding the film comprises embedding a SiN film by alternately supplying a Si-containing gas and a nitrogen-containing gas.

14. The method of claim 13, wherein the nitrogen-containing gas is N₂ plasma.

15. An embedding system for embedding a gap between a plurality of dies in a structure in which the plurality of dies are arranged at intervals on a substrate, comprising:
a fine particle filling apparatus configured to fill the gap with insulating fine particles; and
a film forming apparatus configured to form an insulating film on a surface of the structure by ALD and embed the insulating film in the gap,
wherein the fine particles are embedded in the gap by the fine particle filling apparatus, and the film is filled between the fine particles in the gap by the film forming apparatus, thereby forming an embedding layer in the gap.
